(19) United States
(12) Patent Application Publication
(10) Pub. No.: US 2025/0132196 A1
(43) Pub. Date: Apr. 24, 2025

(54) SEMICONDUCTOR DEVICE HAVING CAPACITOR ARRAY AND METHOD OF FORMING THE SAME

(71) Applicant: NANYA TECHNOLOGY CORPORATION, New Taipei City (TW)

(72) Inventors: Yao-Hsiung KUNG, Taoyuan City (TW); Yu-Li WU, New Taipei City (TW)

(21) Appl. No.: 18/490,777

(22) Filed: Oct. 20, 2023

(51) Int. Cl. H01L 21/768; H01L 21/66; H01L 23/522; H01L 23/532; H01L 27/10

(52) U.S. Cl. CPC H01L 21/76819; H01L 22/26; H01L 23/53295; H10D 1/696; H10D 84/00; H01L 23/5226

(57) ABSTRACT

A method of forming a semiconductor device having a capacitor array includes forming a top electrode plate of the capacitor array in an active region and a periphery region of a substrate; depositing a first oxide layer above the top electrode plate in the active region and the periphery region; removing the top electrode plate in the periphery region; forming a nitride film on the first oxide layer in the active region and in the periphery region; depositing a second oxide layer on the nitride film in the active region and the periphery region; and polishing the second oxide layer to expose the nitride film in the active region.

### BACKGROUND

### Field of Invention

The present invention relates to a semiconductor device having a capacitor array and a method of forming the semiconductor device having the capacitor array.

### Description of Related Art

In the process of forming a capacitor array, thick oxide needs to be removed through chemical mechanical process. However, the thickness of the oxide may up to more than 10000 angstrom. Generally, the loss range increases as the remove amount increases. Therefore, the loss range may up to 1000 angstrom. As a result, the uniformity of CMP process is poor. In addition, endpoint detection cannot be applied. As a result, mean standard deviation is worse.

Accordingly, it is still a development direction for the industry to provide a method of forming a semiconductor device having a capacitor array that can solve the problems mentioned above.

### SUMMARY

The invention provides a method of forming a semiconductor device having a capacitor array.

In one embodiment, the method includes forming a top electrode plate of the capacitor array in an active region and a periphery region of a substrate; depositing a first oxide layer above the top electrode plate in the active region and the periphery region; removing the top electrode plate in the periphery region; forming a nitride film on the first oxide layer in the active region and in the periphery region; depositing a second oxide layer on the nitride film in the active region and the periphery region; and polishing the second oxide layer to expose the nitride film in the active region.

The invention provides a semiconductor device having a capacitor array.

In one embodiment, the semiconductor device having a capacitor array includes a substrate having an active region and a periphery region, a capacitor array in the active region, a first oxide layer, and a nitride film. The includes a bottom electrode plate, a capacitor dielectric layer covering the bottom electrode plate, and a top electrode plate covering the capacitor dielectric layer. The first oxide layer covers the top electrode plate in the active region. The nitride film is at least adjacent to the first oxide layer, and the nitride film includes a first portion extending along a longitudinal direction.

### BRIEF DESCRIPTION OF THE DRAWINGS

The invention can be more fully understood by reading the following detailed description of the embodiment, with reference made to the accompanying drawings as follows:

FIG. 1 is flow chat of a method of forming a semiconductor device having a capacitor array according to one embodiment of the present disclosure.

FIG. 2 to FIG. 9 are cross-sectional views of the method M1 of forming the semiconductor device having the capacitor array in FIG. 1 at various stages according to one embodiment of the present disclosure.

FIG. 10 is flow chat of a method of forming a semiconductor device having a capacitor array according to another embodiment of the present disclosure.

FIG. 11 and FIG. 12 are cross-sectional views of the method of forming the semiconductor device having the capacitor array in FIG. 10 at various stages according to one embodiment of the present disclosure.

### DETAILED DESCRIPTION

Reference will now be made in detail to the present embodiments of the invention, examples of which are illustrated in the accompanying drawings. Wherever possible, the same reference numbers are used in the drawings and the description to refer to the same or like parts.

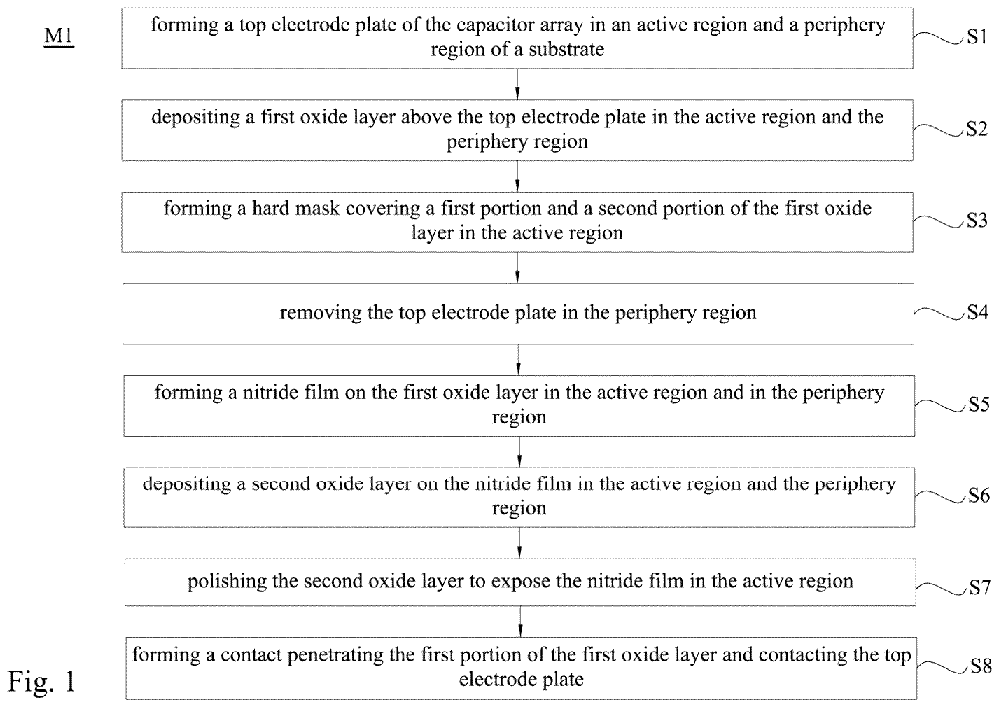

FIG. 1 is a flow chart of a method M1 of forming a semiconductor device having a capacitor array according to one embodiment of the present disclosure. The method starts with step S1 in which a top electrode plate is formed in an active region and a periphery region of a substrate. Thereafter, in step S2, a first oxide layer is deposited above the top electrode plate in the active region and the periphery region. Next, in step S3, a hard mask is formed to cover a first portion and a second portion of the first oxide layer in the active region. Subsequently, in step S4, the top electrode plate in the periphery region is removed. Therefore, in step S5, a nitride film is formed on the first oxide layer in the active region and the periphery region. Next, in step S6, a second oxide layer is deposited on the nitride film in the active region and the periphery region. Subsequently, in step S7, the second oxide layer is polished to expose the nitride film in the active region. Lastly, in step S8, a contact penetrating the first portion of the first oxide layer is formed to contact the top electrode plate. In the following description, the aforementioned steps will be described in detail.

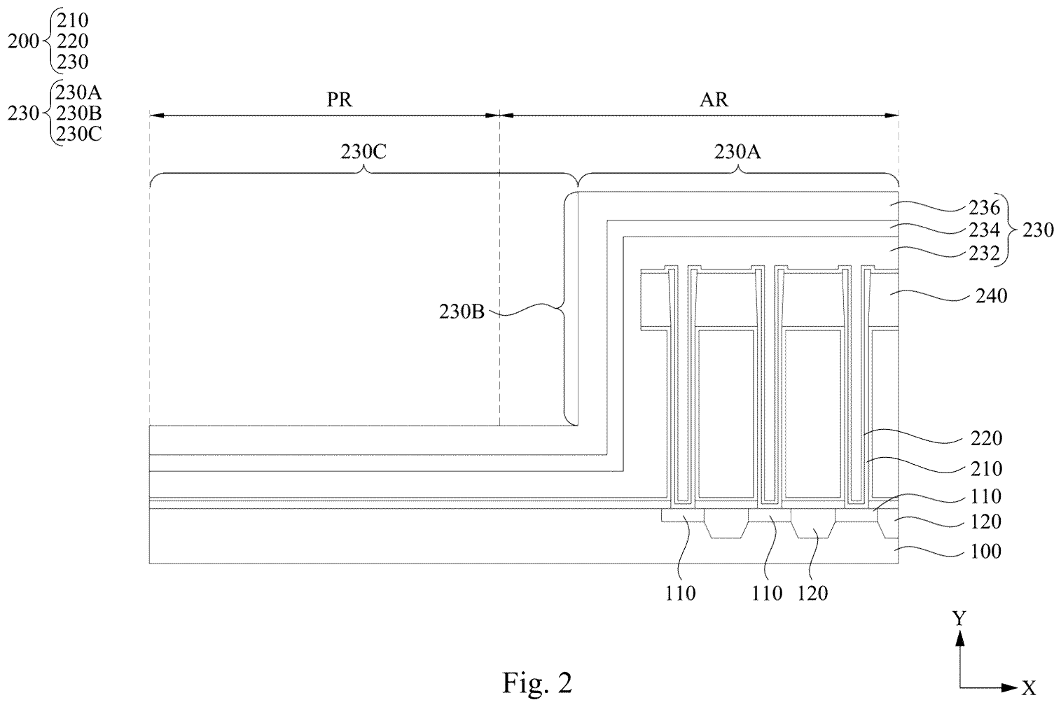

FIG. 2 to FIG. 9 are cross-sectional views of the method M1 of forming the semiconductor device having the capacitor array in FIG. 1 at various stages according to one embodiment of the present disclosure. Reference is made to FIG. 2 and step S1 in FIG. 1. A bottom electrode plate 210, a capacitor dielectric layer 220, and a top electrode plate 230 of a capacitor array 200 are formed on a substrate 100. The substrate 100 includes an active region AR and a periphery region PR arranged along a lateral direction X. The bottom electrode plate 210 and the capacitor dielectric layer 220 are formed in the active region AR, and the top electrode plate 230 is formed both in the active region AR and the periphery region PR.

The substrate 100 includes multiple landing pads 110 and insulating material 120. The landing pad 110 contacts the bottom electrode plate 210 of the capacitor array 200. The substrate 100 further includes active elements (not shown) such as metal-oxide-semiconductor (MOS) below the landing pad 110. The capacitor array 200 further include dielectric layer 240 for supporting the capacitors.

Forming the top electrode plate 230 includes sequentially depositing a titanium nitride (TiN) layer 232, a polymer layer 234, and a tungsten layer 236 along a longitudinal direction Y. The titanium nitride layer 232 is formed on the capacitor dielectric layer 220 in the active region AR and is formed in the periphery region PR. The polymer layer 234 is formed on the titanium nitride layer 232 in the active region AR and in the periphery region PR. The tungsten layer 236 is formed on the polymer layer 234.

The top electrode plate 230 includes a first portion 230A, a second portion 230B, and a third portion 230C. The first portion 230A is a lateral portion located in the active region AR. The second portion 230B is a longitudinal portion located in the active region AR. The third portion 230C is a lateral portion mainly located in the periphery region PR. The second portion 230B is connected with the first portion 230A and the third portion 230C.

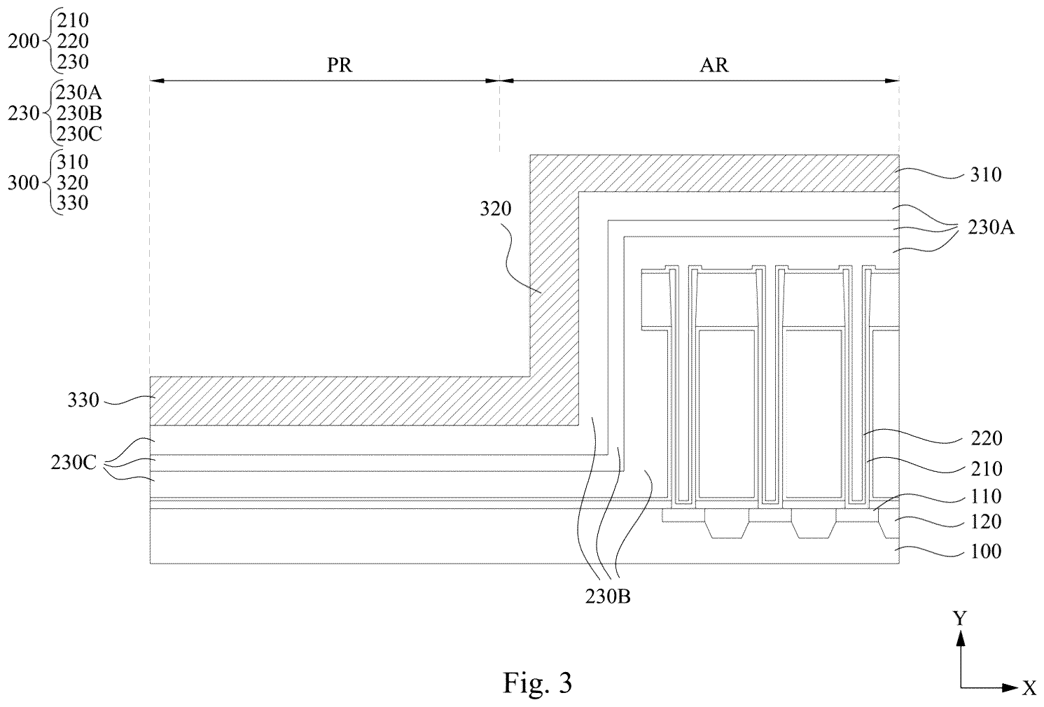

Reference is made to FIG. 3 and step S2 in FIG. 1. A first oxide layer 300 is deposited above the top electrode plate 230 in the active region AR and the periphery region PR. The first oxide layer 300 is conformally formed on the top electrode plate 230. The material of the first oxide layer 300 includes (Tetraethoxysilane, TEOS).

The first oxide layer 300 includes a first portion 310, a second portion 320, and a third portion 330. The first portion 310 is a lateral portion located in the active region AR and above the first portion 230A of the top electrode plate 230. The second portion 320 is a longitudinal portion located in the active region AR adjacent to the second portion 230B of the top electrode plate 230. The third portion 330 is a lateral portion located in the periphery region PR and above the third portion 230C of the top electrode plate 230. The second portion 320 is connected with the first portion 310 and the third portion 330.

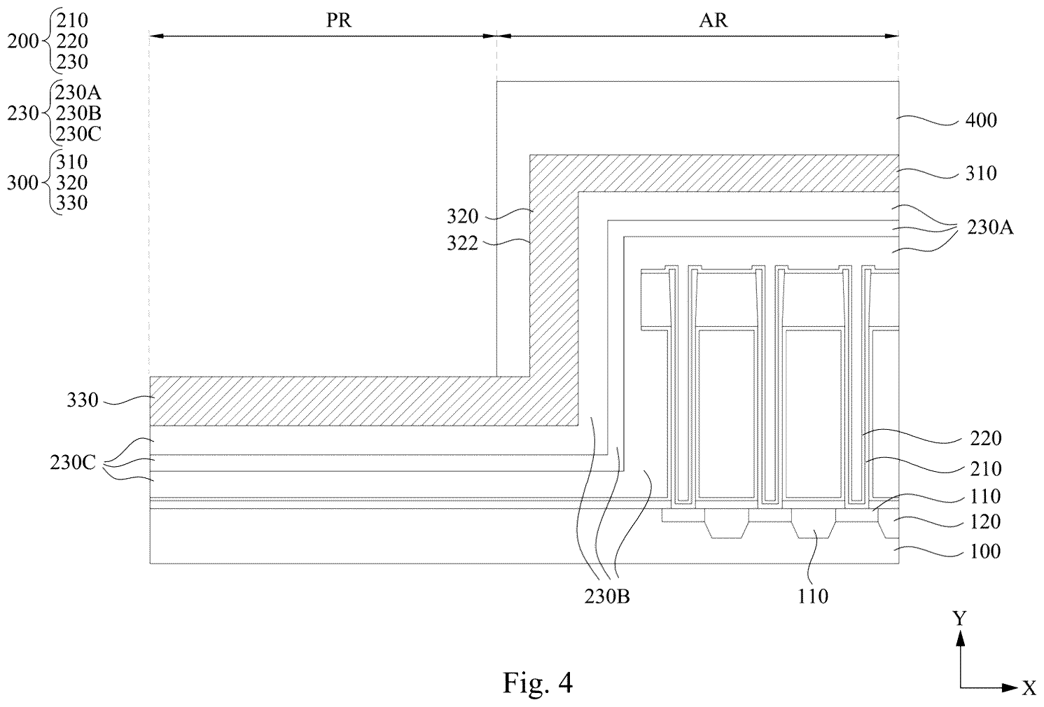

Reference is made to FIG. 4 and step S3 in FIG. 1. A hard mask 400 is formed to cover the first portion 310 and the second portion 320 of the first oxide layer 300 in the active region AR. Specifically, the hard mask 400 includes a longitudinal portion which covers a sidewall 322 of the second portion 320 of the first oxide layer 300.

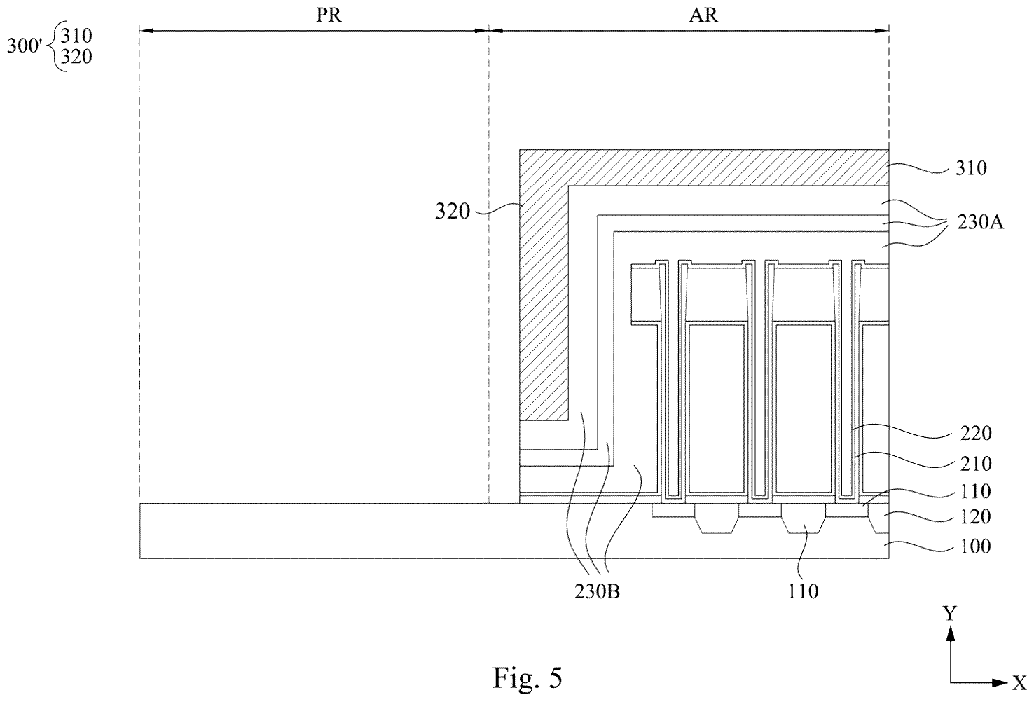

Reference is made to FIG. 4, FIG. 5, and step S4 in FIG. 1. The top electrode plate 230 in the periphery region PR is removed. Specifically, the third portion 330 of the first oxide layer 300 and the third portion 230C of the top electrode plate 230 are both removed until the substrate 100 is exposed. The third portion 330 of the first oxide layer 300 and the third portion 230C of the top electrode plate 230 are removed through dry etch. That is, the first portion 310 and the second portion 320 of the remained first oxide layer 300′ are protected by the hard mask 400. After removing the top electrode plate 230 in the periphery region PR, the hard mask 400 is removed.

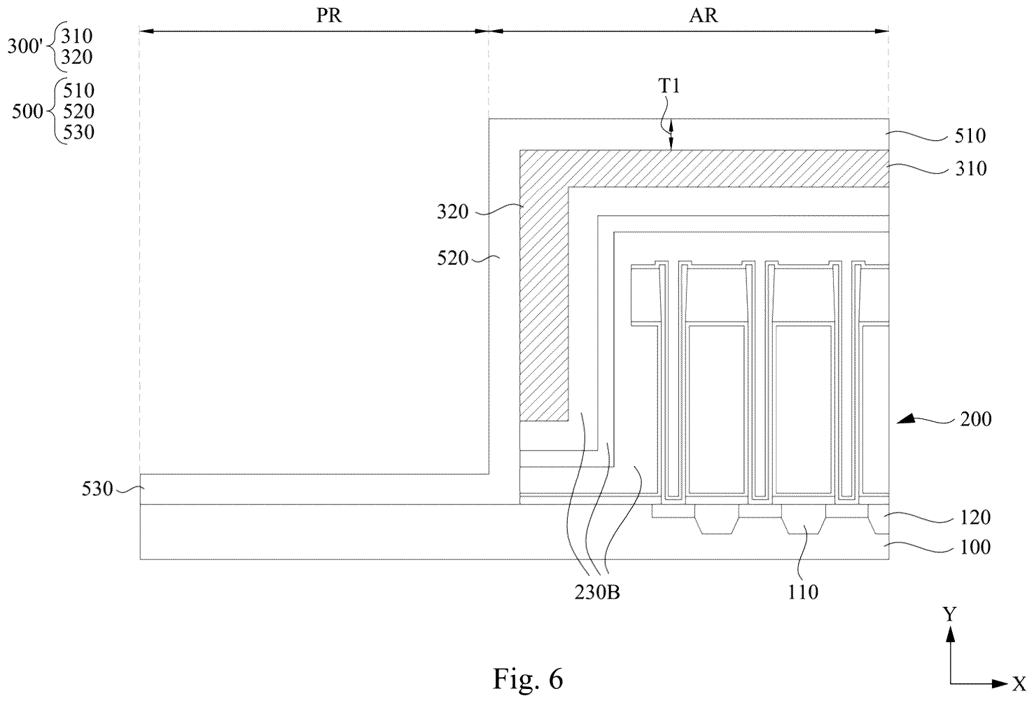

Reference is made to FIG. 6 and step S5 in FIG. 1. A nitride film 500 is formed on the remained first oxide layer 300′ in the active region AR and formed on the substrate 100 in the periphery region PR. The nitride film 500 at least covers the first portion 310 and the second portion 320 of the remained first oxide layer 300′ in the active region. The thickness T1 of the nitride film 500 is about 20 nm.

Specifically, the nitride film 500 is conformally formed on the remained first oxide layer 300′ and the substrate 100. The nitride film 500 includes a first portion 510, a second portion 520, and a third portion 530. The first portion 510 is a lateral portion located in the active region AR and above the first portion 310 of the remained first oxide layer 300′. The second portion 520 is a longitudinal portion located in the active region AR. The third portion 530 is a lateral portion located in the periphery region PR and above the substrate 100. The nitride film 500 is deposited as a stop layer in the subsequently process.

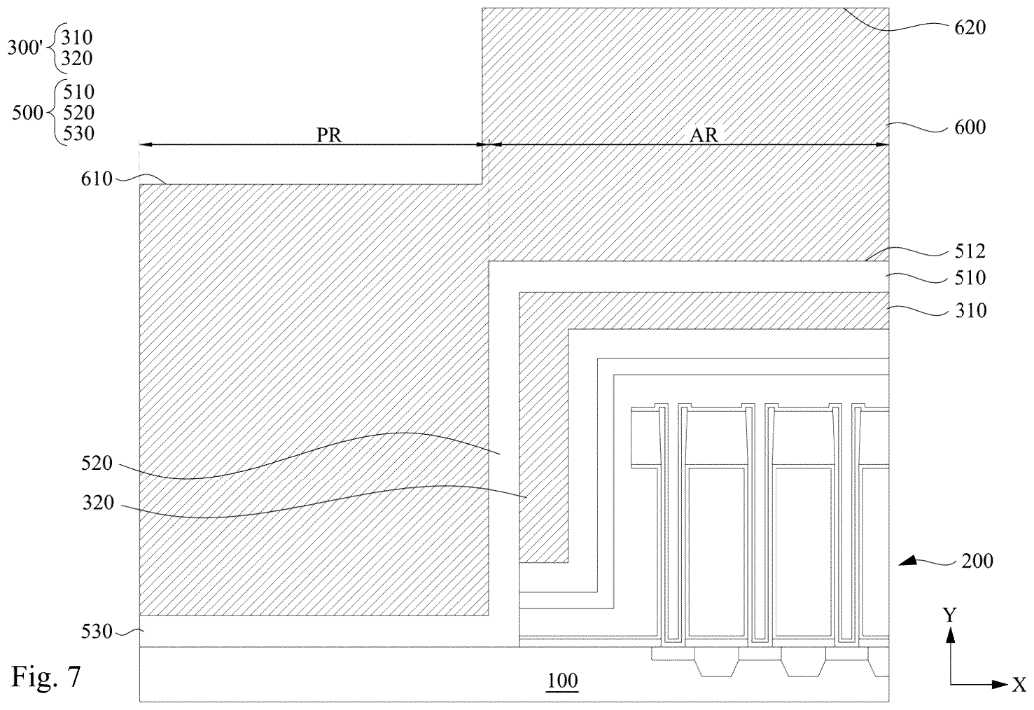

Reference is made to FIG. 7 and step S6 in FIG. 1. A second oxide layer 600 is deposited on the nitride film 500 in the active region AR and the periphery region PR. The second oxide layer 600 is formed to fill the gap between the active region AR and the periphery region PR. In other words, a top surface 610 of the second oxide layer 600 in the periphery region PR is at least higher than a top surface 512 of the first portion 510 of the nitride film 500 in the active region AR. Specifically, a top surface 620 of the second oxide layer 600 in the active region AR is higher than the top surface 610 of the second oxide layer 600. The material of the second oxide layer 600 includes (Tetraethoxysilane, TEOS).

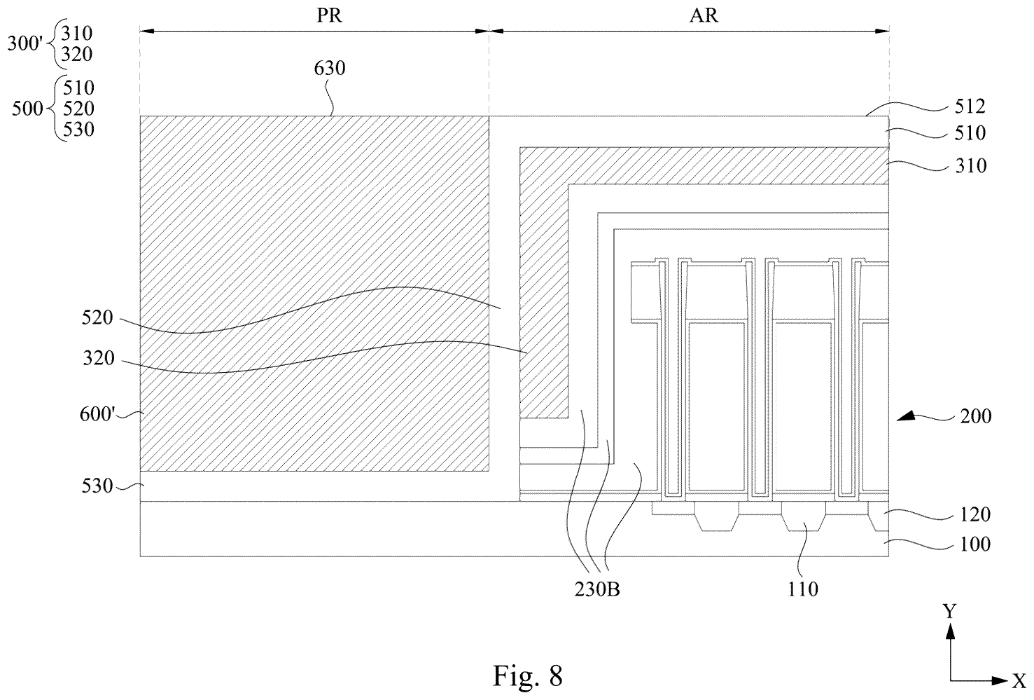

Reference is made to FIG. 8 and step S7 in FIG. 1. The second oxide layer 600 is polished to expose the nitride film 500 in the active region. Specifically, the top surface 512 of the first portion 510 of the nitride film 500 is exposed. The second oxide layer 600 is polished through chemical mechanical polish (CMP). In this step, endpoint detection (EPD) mode is applied such that the polish process is stopped at the interface between the nitride film 500 and the second oxide layer 600. The top surface 512 of the first portion 510 of the nitride film 500 is level with a top surface 630 of the remained second oxide layer 600′. As such, CMP post mean standard deviation is improved and the post range is reduced. Therefore, the thickness uniformity of CMP process can be improved even when the thickness of the second oxide layer 600 is more than 10000 angstrom (e.g., may up to 14000 angstrom), and there is no need to use extra etching back process to reduce step height first. In addition, high rate slurry can be imported by using the nitride film as the stop layer.

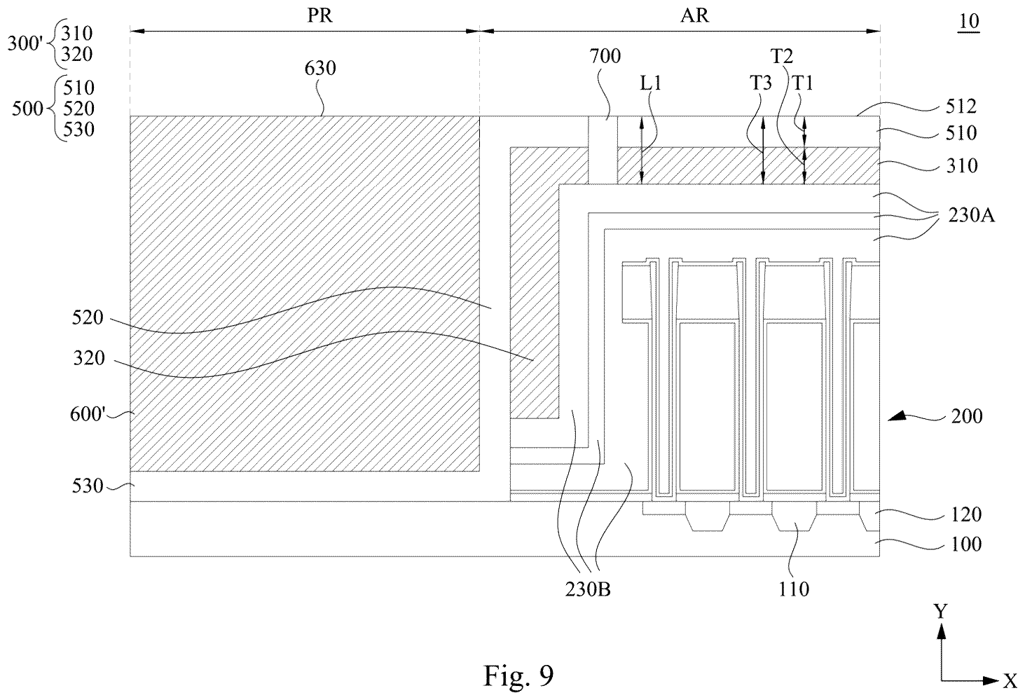

Reference is made to FIG. 9 and step S8 in FIG. 1. A contact 700 is formed penetrating the first portion 310 of the first oxide layer 300 and the first portion 510 of the nitride film 500. The contact 700 is electrically connected with the first portion 230A of the top electrode plate 230. A total thickness T3 of the first portion 310 of the first oxide layer 300 and the first portion 510 of the nitride film 500 is substantially the same as the length L1 of the contact 700. In other words, the thickness T2 of the first portion 310 of the first oxide layer 300 and the thickness T1 of the first portion 510 of the nitride film 500 are respectively predetermined in step S2 and step S5 based on the length L1 of the contact 700. As such, there is no need to depositing extra oxide layer in the active region AR before the step of forming the nitride film 500 or the contact 700 to adjust the total thickness T3 to a target thickness.

For example, the target thickness of the total thickness T3 may be 5000 angstrom (500 nm). Therefore, the step of depositing the first oxide layer 300 is performed such that the thickness T1 is close to 480 nm, and the thickness T1 of the nitride film 500 is about 20 nm.

Based on the method M1, the capacitor array 200 of the semiconductor device 10 is finished. The semiconductor device 10 includes the substrate 100, the capacitor array 200, a first oxide layer 300′ in the active region AR (i.e., the remained first oxide layer 300′), a nitride film 500, a second oxide layer 600′ (i.e., the remained second oxide layer 600′) in the periphery region PR, and a contact 700. Since the CMP process is improved, the semiconductor device 10 has uniform interface that can be beneficial for the structured formed thereon in the subsequent process.

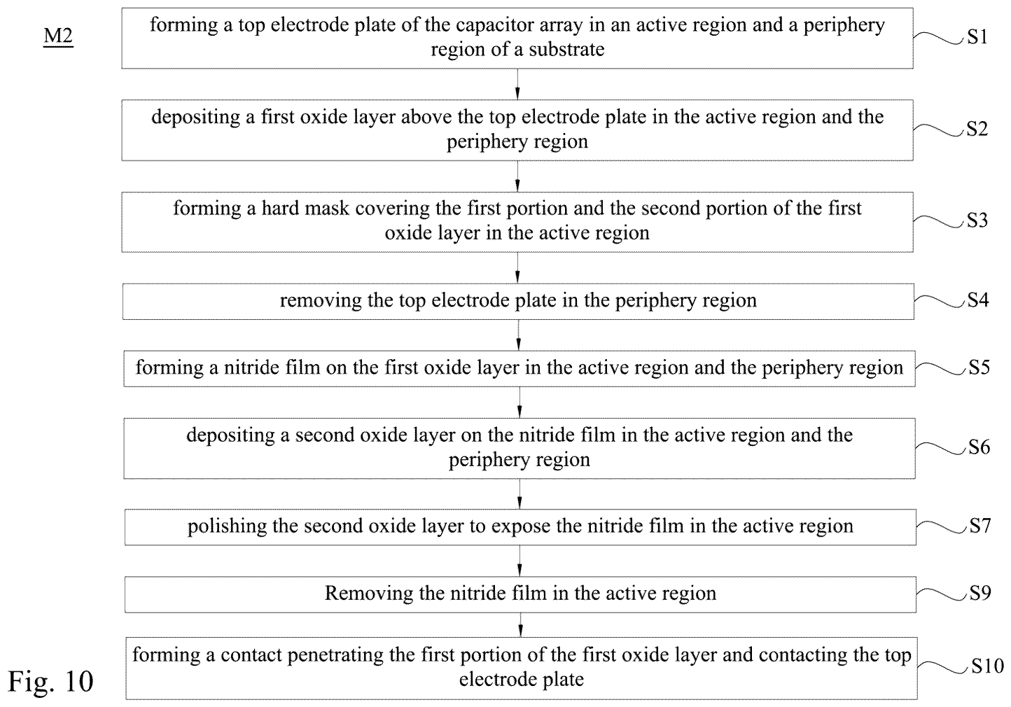

FIG. 10 is flow chat of a method M2 of forming a semiconductor device having a capacitor array according to another embodiment of the present disclosure. Step S1 to step S7 of the method M2 are substantially the same as Step S1 to step S7 of method M1. The method M2 further includes step S9 and step S10 after step S7. The method M2 includes the advantages of the method M1 mentioned above, and therefore the description is not repeated hereinafter. In step S9, the nitride film is removed. In step S10, a contact penetrating the first portion of the first oxide layer is formed to contact the top electrode plate. In the following description, the aforementioned step S9 and step S10 will be described in detail.

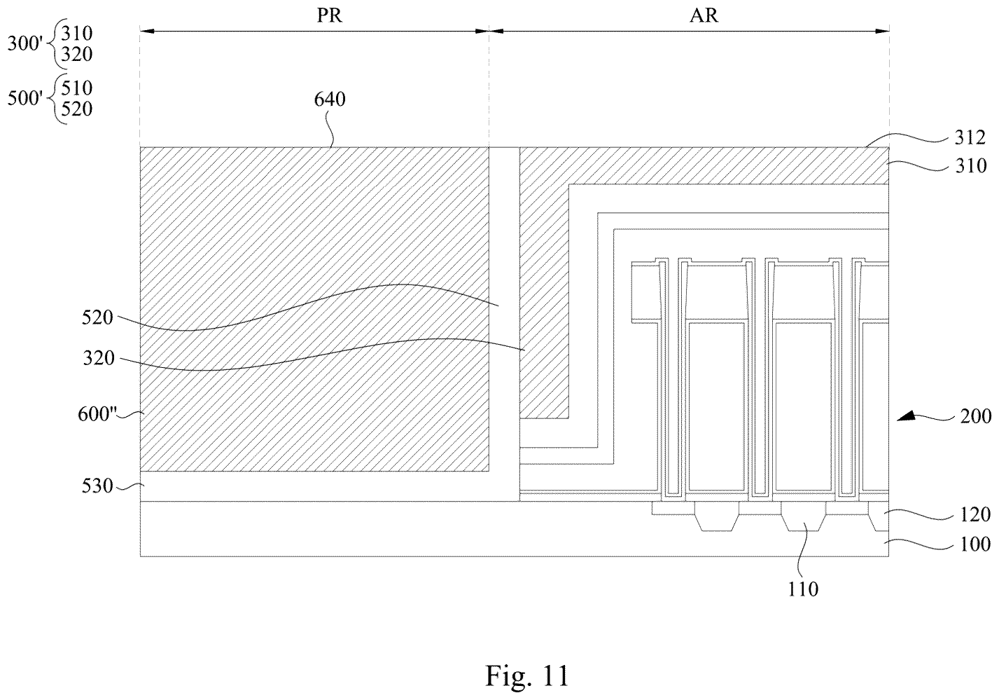

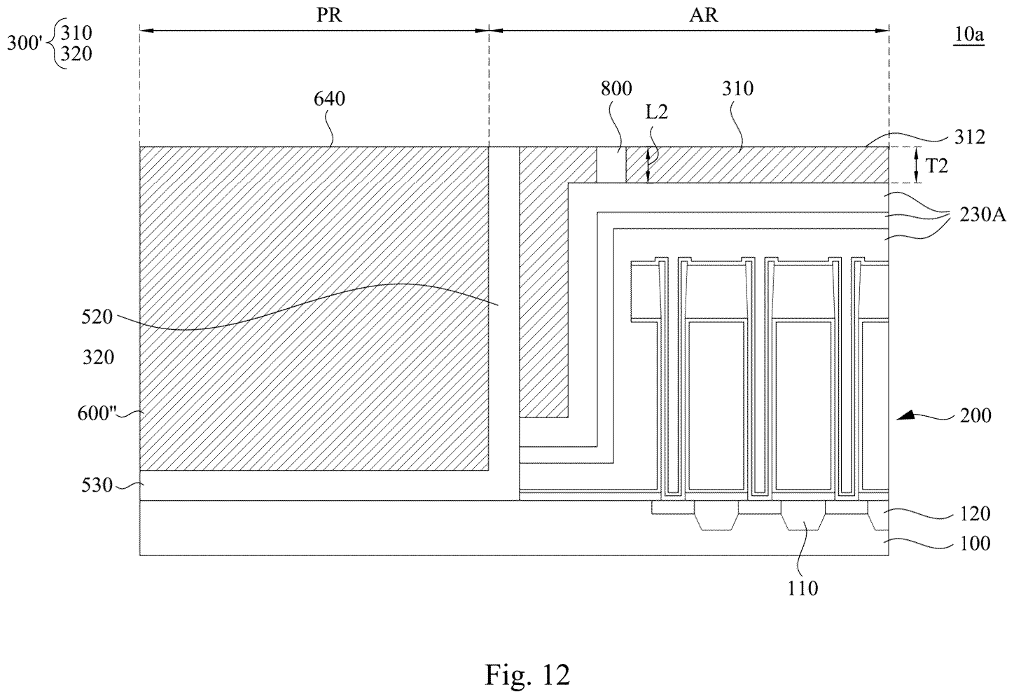

FIG. 11 and FIG. 12 are cross-sectional views of the method of forming the semiconductor device having the capacitor array 200a in FIG. 10 at various stages according to one embodiment of the present disclosure. Reference is made to FIG. 9, FIG. 11 and step S9 in FIG. 10. The first portion 510 of the nitride film 500 in the active region AR is removed. Specifically, a portion of the second oxide layer 600 in the periphery region PR is removed such that the top surface 312 of the first portion 310 of the remained first oxide layer 300′ is level with a top surface 640 of the remained second oxide layer 600″ in the periphery region PR. After this step, a remained nitride film 500′ includes the second portion 520 and the third portion 530.

In some embodiment, the first portion 510 of the nitride film 500 is etched first. Then, an upper part of the second oxide layer 600 in the periphery region PR is polished to smooth the top surface 640 until the top surface 640 is level with the top surface 312.

In some other embodiment, the first portion 510 of the nitride film 500 in the active region AR and the second oxide layer 600 in the periphery region PR are etched simultaneously. For example, an etching selectively between the material of the nitride film 500 and the material of the second oxide layer 600 is 1:1.

Reference is made to FIG. 12 and step S10 in FIG. 10. A contact 800 is formed penetrating the first portion 310 of the first oxide layer 300. The contact 800 is electrically connected with the first portion 230A of the top electrode plate 230. The thickness T2 of the first portion 310 of the first oxide layer 300 is substantially the same as the length L2 of the contact 800. In other words, the thickness T2 of the first portion 310 of the first oxide layer 300 is predetermined in step S2 based on the length L2 of the contact 800. As such, there is no need to depositing extra oxide layer in the active region AR before the step of forming the nitride film 500 or after the step of removing the nitride film 500 to adjust the thickness T2 to a target thickness.

Based on the method M2, the capacitor array 200 of the semiconductor device 10a is finished. The semiconductor device 10a includes the substrate 100, the capacitor array 200, a first oxide layer 300′ (i.e., the remained first oxide layer 300′), a nitride film 500′ (i.e., the remained nitride film 500′) adjacent to the remained first oxide layer 300′, a second oxide layer 600″ (i.e., the remained second oxide layer 600″) in the periphery region PR, and a contact 800. Since the CMP process is improved, the semiconductor device 10a has uniform interface that can be beneficial for the structured formed thereon in the subsequent process.

In summary, by forming the nitride film between on the first oxide layer, the CMP process of removing the second oxide layer thereon can use EPD mode. Therefore, the CMP post mean standard deviation is improved and the post range is reduced. Therefore, the thickness uniformity of CMP process can be improved even when the thickness of the second oxide layer is more than 10000 angstrom, and there is no need to use extra etching back process to reduce step height first. In addition, high rate slurry can be imported by using the nitride film as the stop layer.

Although the present invention has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims.

What is claimed is:

1. A method of forming a semiconductor device having a capacitor array, comprising:
forming a top electrode plate of the capacitor array in an active region and a periphery region of a substrate;
depositing a first oxide layer above the top electrode plate in the active region and the periphery region;
removing the top electrode plate in the periphery region;
forming a nitride film on the first oxide layer in the active region and in the periphery region;
depositing a second oxide layer on the nitride film in the active region and the periphery region; and
polishing the second oxide layer to expose the nitride film in the active region.

2. The method of forming the semiconductor device having the capacitor array of claim 1, wherein forming the top electrode plate of the capacitor array in the active region and the periphery region further comprises:
forming a titanium nitride (TiN) layer on a bottom electrode plate and a capacitor dielectric layer in the active region and in the periphery region; and
forming a polymer layer on the titanium nitride layer in the active region and the periphery region.

3. The method of forming the semiconductor device having the capacitor array of claim 1, wherein the first oxide layer comprises a first portion extending along a lateral direction, a second portion extending along a longitudinal direction, and a third portion along the lateral direction, the first portion and the second portion are in the active region, the third portion is in the periphery region, and the method of forming the capacitor array further comprises:
before removing the top electrode plate in the periphery region, forming a hard mask covering the first portion and the second portion of the first oxide layer in the active region.

4. The method of forming the semiconductor device having the capacitor array of claim 3, further comprising:
forming a contact penetrating the first portion of the first oxide layer and the nitride film and contacting the top electrode plate, wherein depositing the first oxide layer above the top electrode plate in the active region and the periphery region further comprises:
depositing the first oxide layer such that a total thickness of the first portion of the first oxide layer and the nitride film in the active region is substantially the same as a length of the contact.

5. The method of forming the semiconductor device having the capacitor array of claim 3, wherein forming the nitride film on the first oxide layer in the active region and in the periphery region further comprises:
forming the nitride film at least covering the first portion and the second portion of the first oxide layer in the active region and covering the substrate in the periphery region.

6. The method of forming the semiconductor device having the capacitor array of claim 1, wherein depositing the second oxide layer on the nitride film in the active region and the periphery region further comprises:
depositing the second oxide layer such that a top surface of the second oxide layer in the periphery region is higher than a top surface of the nitride film in the active region.

7. The method of forming the semiconductor device having the capacitor array of claim 1, wherein polishing the second oxide layer to expose the nitride film in the active region further comprises:
applying an endpoint detection (EPD) mode control such that a top surface of the nitride film in the active region is level with a top surface of a remained second oxide layer in the periphery region.

8. The method of forming the semiconductor device having the capacitor array of claim 1, further comprising:
removing the nitride film in the active region such that a top surface of the first oxide layer in the active region is level with a top surface of a remained second oxide layer in the periphery region.

9. The method of forming the semiconductor device having the capacitor array of claim 8, wherein removing the nitride film further comprises:
etching the nitride film in the active region to expose the first oxide layer in the active region; and
polishing the second oxide layer in the periphery region.

10. The method of forming the semiconductor device having the capacitor array of claim 8, wherein removing the nitride film further comprises:
etching the nitride film in the active region and the second oxide layer in the periphery region simultaneously.

11. The method of forming the semiconductor device having the capacitor array of claim 8, further comprising:
forming a contact penetrating the first oxide layer and contacting the top electrode plate, wherein depositing the first oxide layer above the top electrode plate in the active region and the periphery region further comprises:
depositing the first oxide layer such that a thickness of the first oxide layer in the active region is substantially the same as a length of the contact.

12. A semiconductor device having a capacitor array, comprising:
a substrate having an active region and a periphery region;
a capacitor array in the active region, comprising:
a bottom electrode plate;
a capacitor dielectric layer covering the bottom electrode plate; and
a top electrode plate covering the capacitor dielectric layer;
a first oxide layer covering the top electrode plate in the active region; and
a nitride film at least adjacent to the first oxide layer, wherein the nitride film comprises a first portion extending along a longitudinal direction.

13. The semiconductor device having the capacitor array of claim 12, further comprising a contact penetrating the first oxide layer and contacting the top electrode plate, wherein a thickness of the first oxide layer is substantially the same as a length of the contact.

14. The semiconductor device having the capacitor array of claim 12, further comprising a second oxide layer in the periphery region, wherein a top surface of the second oxide layer is level with a top surface of the first oxide layer.

15. The semiconductor device having the capacitor array of claim 12, wherein the nitride film further comprises a second portion extending along a lateral direction in the active region.

16. The semiconductor device having the capacitor array of claim 15, further comprising a contact penetrating the first oxide layer and the second portion of the nitride film and contacting the top electrode plate, wherein a total thickness of the first portion of the first oxide layer and the second portion of the nitride film is substantially the same as a length of the contact.

17. The semiconductor device having the capacitor array of claim 15, further comprising a second oxide layer in the periphery region, wherein a top surface of the second oxide layer is level with a top surface of the second portion of the nitride film.

18. The semiconductor device having the capacitor array of claim 12, wherein the first oxide layer further comprises a first portion extending along a lateral portion and a second portion extending along the longitudinal direction in the active region.

19. The semiconductor device having the capacitor array of claim 12, wherein the top electrode plate comprises a first portion extending along a lateral portion and a second portion extending along the longitudinal direction.

20. The semiconductor device having the capacitor array of claim 12, wherein the nitride film further comprises a third portion extending along a lateral direction in the periphery region.
